(19) United States
(12) Patent Application Publication
(10) Pub. No.: US 2025/0379554 A1
(43) Pub. Date: Dec. 11, 2025

(54) PIEZOELECTRIC BOUNDARY ACOUSTIC WAVE DEVICE WITH A METALLIC OVERLAY

(71) Applicant: Qorvo US, Inc., Greensboro, NC (US)

(72) Inventors: Marc Solal, Longwood, FL (US); Christian Huck, Munich (DE)

(21) Appl. No.: 19/088,792

(22) Filed: Mar. 24, 2025

Related U.S. Application Data
(60) Provisional application No. 63/657,465, filed on Jun. 7, 2024.

(51) Int. Cl. H03H 9/02

(52) U.S. Cl. CPC H03H 9/0222

(57) ABSTRACT

A piezoelectric boundary acoustic wave (PBAW) device includes a piezoelectric substrate, an interdigital transducer on the piezoelectric substrate, the interdigital transducer having electrodes arranged with an electrode period, a dielectric embedding layer with the electrodes embedded therein, and a metallic overlaying layer on the dielectric embedding layer.

### CROSS REFERENCE TO RELATED APPLICATION

This application claims priority to U.S. Patent Application No. 63/657,465, filed Jun. 7, 2024, which is incorporated by reference herein in its entirety.

### FIELD OF THE DISCLOSURE

The technology disclosed herein relates generally to piezoelectric boundary acoustic wave (PBAW) devices, also called PBAW filters, and more particularly to PBAW devices with a metallic overlay for application in radio frequency (RF) filtering for wireless communications.

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependence on the alternating electrical signal. Acoustic wave devices leverage this frequency dependence to provide one or more functions.

Exemplary acoustic wave devices include surface acoustic wave (SAW) filters. In the context of SAW filters, an electrode pitch of an interdigital transducer (IDT) primarily defines a center frequency of the resonators. One issue for SAW filters is the need to use a package with a cavity. This results in an increased device size. The escalating demands of modern RF communication systems necessitate that acoustic wave devices offer increasingly compact form factors. An approach to solve this issue is boundary wave devices. Example boundary wave devices include piezoelectric boundary acoustic wave (PBAW) devices. PBAW devices add an overlaying layer usually made of a fast material on top of an IDT on a piezoelectric substrate. Such a structure suppresses the need for a cavity package. In recent years, PBAW devices have been successfully used in wireless communication systems as a result of their small size and low insertion loss provided by resonator-type structures, built on piezoelectric substrates with high electromechanical coupling factors.

Yet, conventional PBAW devices have reached a development bottleneck. Due to the overlaying layer made of a fast material, the resonance frequency of the PBAW devices may be pushed above the substrate cutoff frequency, resulting in bulk radiation losses. One possible approach is to increase a thickness of an IDT to push the resonance frequency down. PBAW devices suffer several other issues. One issue is the difficulty of handling power. This is due at least in part to the fact that the device is normally embedded inside a dielectric material which often does not have good thermal conductivity. Another issue is the difficulty of laying out the device without having resistive losses in the connections between resonators. Using a metallic overlay helps solve these problems.

### SUMMARY

Example aspects of the present disclosure provide solutions that allow to make acoustic wave filters without a cavity package by using boundary waves and to maintain low losses. Without the need for a cavity package, the size of the acoustic wave filters can be reduced. Also, this technology allows in principle to stack several dies to reduce the size even more. Some exemplary acoustic wave filters include an IDT disposed on a piezoelectric substrate and covered with an acoustically fast dielectric layer to avoid using a cavity package. A metallic overlaying layer is disposed on the dielectric layer for improving thermal dissipation and reducing layout losses without compromising acoustical performance.

In an exemplary embodiment, a piezoelectric boundary acoustic wave (PBAW) device includes a piezoelectric substrate, an interdigital transducer on the piezoelectric substrate, the interdigital transducer having electrodes arranged with an electrode period, a dielectric embedding layer with the electrodes embedded therein, and a metallic overlaying layer on the dielectric embedding layer.

In another exemplary embodiment, a PBAW device includes a piezoelectric substrate, an interdigital transducer on the piezoelectric substrate, dielectric embedding layers with the electrodes embedded therein, and metallic overlaying layers on the dielectric embedding layer. The interdigital transducer has electrodes arranged with an electrode period. A thickness of the metallic overlaying layer is larger than the electrode period.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description, serve to explain the principles of the disclosure.

FIGS. 1A and 1B illustrate perspective and cross-sectional views of a conventional boundary acoustic wave device.

FIG. 2 illustrates the concept of Euler angles and how they describe the crystalline orientation of a material layer, according to some aspects of the present disclosure.

FIG. 3 illustrates distribution of displacements of boundary acoustic waves of a boundary acoustic wave device, according to some aspects of the present disclosure.

FIGS. 4 and 5 illustrate cross-sectional views of various embodiments of exemplary boundary wave devices, according to some aspects of the present disclosure.

FIG. 6 illustrates a top view of an exemplary boundary wave device, according to some aspects of the present disclosure.

FIGS. 7A, 7B, 7C, 8A, 8B, 9A, 9B, 10A, 10B, and 10C illustrate simulated performance of exemplary boundary wave devices, according to some aspects of the present disclosure.

FIG. 11 illustrates an equivalent circuit of an exemplary boundary wave device, according to some aspects of the present disclosure.

FIG. 12 illustrates a block diagram of an exemplary wireless communication device, according to some aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Small surface acoustic wave (SAW) filters have been strongly needed in a radio frequency (RF) filter for an RF communication system. In order to meet this requirement, SAW filters may use chip size package (CSP) technology. However, cavity formation is required on the surface of chips, where SAW propagates, restricting the miniaturization of SAW filters. On the other hand, a boundary acoustic wave device in which elastic wave energy concentrates near the boundary does not require cavity formation. Thus, it is expected that a device using boundary acoustic wave will realize a simple package structure with a small form factor. A device using boundary acoustic wave can be made by inserting an interdigital transducer (IDT) at the interface (boundary) between a piezoelectric material and another material. The other material can be a piezoelectric material or other than a piezoelectric material, such as a dielectric material. With the piezoelectric material forming one side of the boundary, such a device is referred to as a piezoelectric boundary acoustic wave (PBAW) device.

The Stoneley wave and shear-horizontal (SH) type boundary acoustic wave are known as boundary acoustic waves. The Stoneley wave mainly consists of a longitudinal wave (P) and a shear vertical wave (SV) components. The SH-type boundary acoustic wave mainly consists of an SH component. Usually, the electromechanical coupling coefficient k², which characterizes the ability to realize wide relative bandwidths, is larger for SH-type boundary waves.

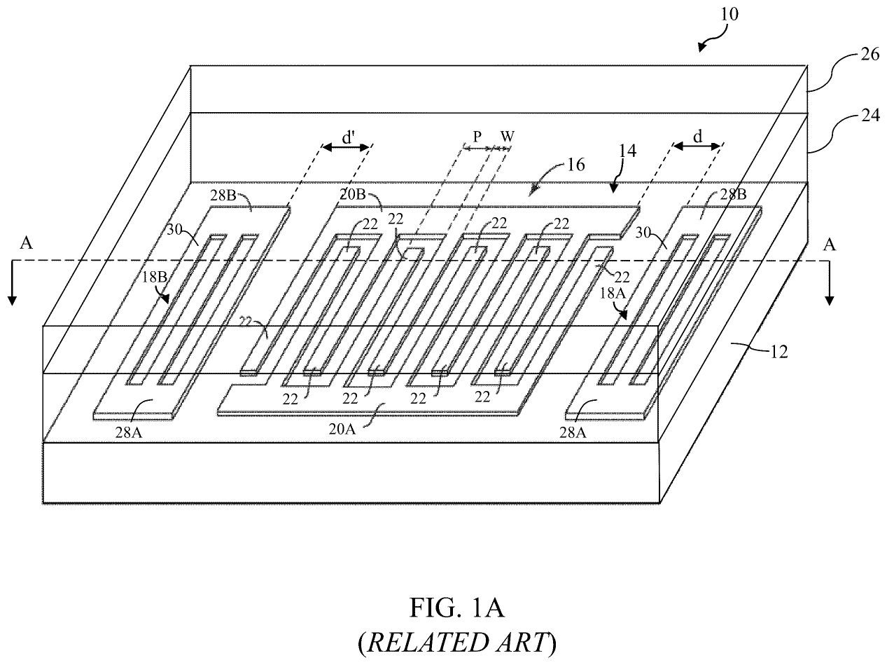

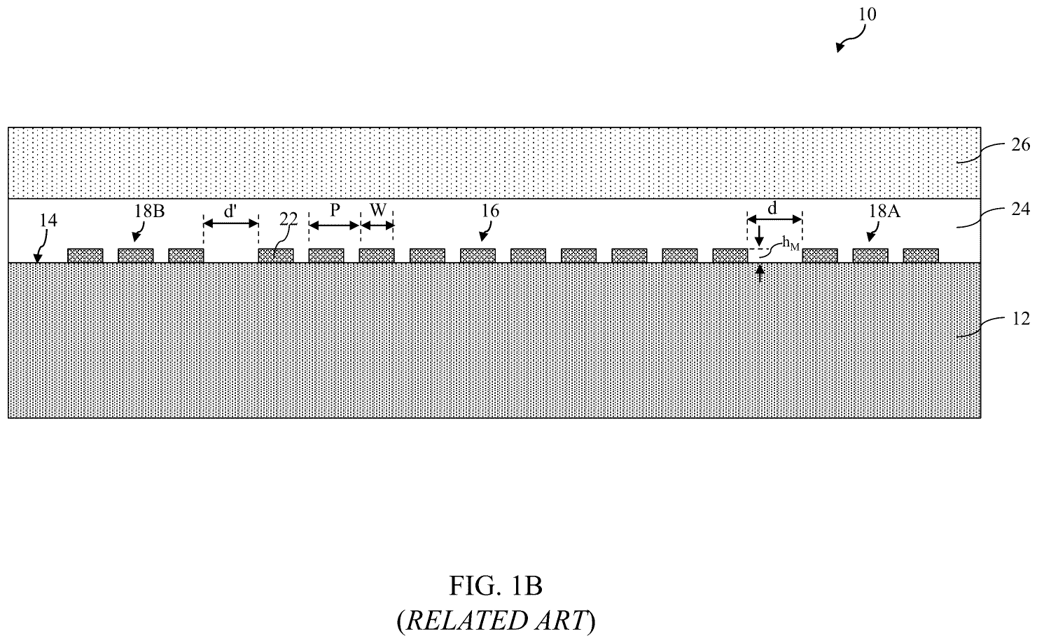

Before addressing exemplary aspects of the present disclosure, a brief discussion of a conventional approach to a PBAW device and its limitations is provided with reference to FIGS. 1A and 1B.

FIG. 1A shows a perspective view of a conventional PBAW device 10. FIG. 1B shows a cross-sectional view of the PBAW device 10 cut along the A-A line in FIG. 1A. Referring to FIGS. 1A and 1B collectively, the PBAW device 10 may comprise a piezoelectric substrate 12 for providing an excitation and a propagation of an acoustic wave. In some embodiments, the piezoelectric substrate 12 is a single crystal piezoelectric substrate. In furtherance of some embodiments, the piezoelectric substrate 12 is a single crystal lithium niobate (LN) substrate or a single crystal lithium tantalate (LT) substrate. In some cases, the piezoelectric substrate can be replaced by a substrate with one or several layers, the top layer being a piezoelectric material. Typical examples would use a layer of lithium tantalate or lithium niobate on a substrate of silicon or silicon carbide. An intermediate layer of silicon oxide may be present between the piezoelectric layer and the substrate. It is understood that the piezoelectric substrates described in this text can be in fact layered substrates.

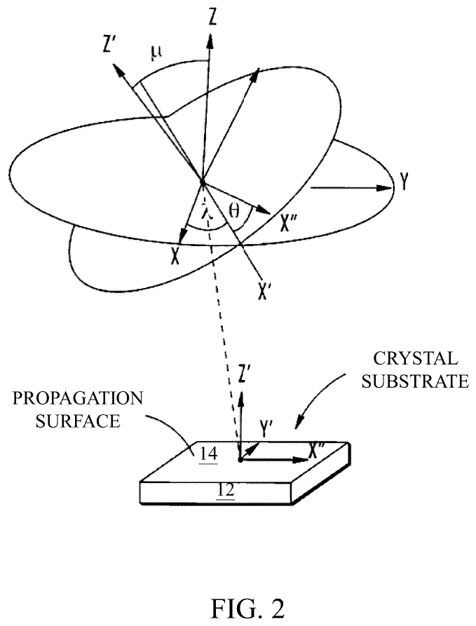

In some embodiments, the piezoelectric substrate 12 may be Y-rotated. FIG. 2 depicts an example of Euler angles (λ, μ, θ) that may provide reference for the Y-rotation. In these embodiments, the shear wave may propagate in the X-direction. The piezoelectric substrate 12 may in some embodiments be referred to as a Y-rotated, X-propagating lithium niobate (YX-LN) substrate or a Y-rotated, X-propagating lithium tantalate (YX-LT) substrate. For example, regarding a YX-LN substrate or a YX-LT substrate, Y+18° denotes a 18° Y-rotation. Since the Euler angle μ defines the rotation from a plane with normal Z while Y+α defines a rotation from a plane with Y normal, the angle μ is related to a by the relation μ=α−90°. For a propagation along X axis, the other Euler angle λ and θ are 0.

Still referring to FIGS. 1A and 1B, an interdigital transducer (IDT) 16 is disposed on the top surface 14 of the piezoelectric substrate 12. A first reflector structure 18A is disposed on the top surface 14 of the piezoelectric substrate 12 adjacent to the IDT 16 with a separation d, and a second reflector structure 18B is disposed on the top surface 14 of the piezoelectric substrate 12 adjacent to the IDT 16 opposite the first reflector structure 18A with a separation d′ where d′ is often equal to d. In some embodiments, the reflector structures 18A and 18B (collectively as reflector structures 18) are omitted in the PBAW device 10. The IDT 16 and the reflector structures 18 (if present) may be made of copper (Cu), gold (Au), tungsten (W), platinum (Pt), aluminum (Al), titanium (Ti) or other suitable metal or metal alloy. It may use multilayer metallic electrodes to simplify the fabrication process, to improve the power durability and/or to combine the material properties (for example high density low conductivity tungsten or platinum with low density high conductivity aluminum). In practical devices, the period P, the electrode width W may vary along the device, but this variation is normally small and can be neglected when considering the guiding or not of the modes.

The IDT 16 includes a first comb electrode 20A and a second comb electrode 20B (collectively referred to as comb electrodes 20), each of which includes a number of electrode fingers 22 that are interleaved with one another, with the finger ends shorting to respective busbars as shown. The electrode fingers 22 have an electrode height (thickness) hm. A lateral distance between adjacent electrode fingers 22 of the first comb electrode 20A and the second comb electrode 20B defines an electrode period (or referred to as electrode pitch) P of the IDT 16. A finger width W of the adjacent electrode fingers 22 over the electrode period P may define a metallization ratio (or referred to as duty factor) M of the IDT 16, which may dictate certain operating characteristics of the PBAW device 10. In some embodiments, the separation d is larger than the electrode pitch P. In some embodiments, the separation d is close to the separation between consecutive electrodes in the IDT (d≈P−W). In the depicted embodiment, each of the reflector structures 18 has a first busbar 28A and a second busbar 28B connected by fingers 30. The fingers 30 of the reflector structures 18 may have the same width (W) and pitch (P) as the electrode fingers 22 of the IDT 16.

The IDT 16 is embedded in an embedding layer 24. The embedding layer 24 may have a positive temperature coefficient of frequency (TCF). In some embodiments, the embedding layer 24 is a silicon oxide (SiO₂) layer. In other embodiments, the embedding layer 24 may be some other dielectric material.

In some embodiments, the PBAW device 10 may further include an additional material 26 overlaying the embedding layer 24. The additional material 26 may also be referred to as an overlaying layer 26. In some embodiments, the overlaying layer 26 may be made of silicon oxide (SiO₂), silicon nitride (Si₃N₄), aluminum nitride (AlN), aluminum oxide (AlO) and/or some other material. The overlaying layer 26 may be specifically chosen to have an acoustic velocity greater than that of the embedding layer 24. By having a greater acoustic velocity than the embedding layer 24, acoustic motion on a top surface of the overlaying layer 26 may be suppressed. In embodiments, the overlaying layer 26 may be flat, as depicted in FIG. 1B, while in other embodiments the overlaying layer 26 may be some other shape such as rounded. It is also possible to stack another die on top of the overlaying layer.

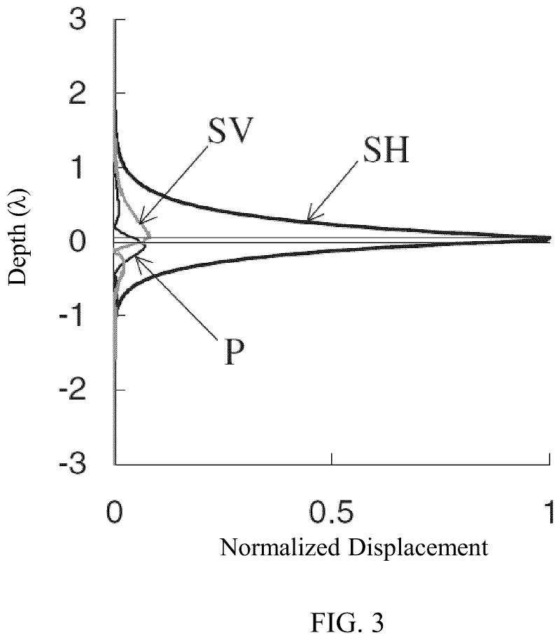

In operation, an alternating electrical input voltage provided between the first comb electrode 20A and the second comb electrode 20B is transduced into a mechanical signal in the piezoelectric substrate 12, resulting in one or more acoustic waves therein. In the case of the PBAW device, depending on the substate orientation, the resulting acoustic waves may be mostly a shear-horizontal (SH) type boundary acoustic wave. For example, FIG. 3 shows the calculated displacement for a wave propagating at the interface between a piezoelectric substrate 12 of lithium niobate (LN) and an embedding layer 24 of silicon oxide (SiO₂). An IDT 16 made of a uniform gold film with a thickness of 0.062 is present at the interface. The propagating mode is predominately in a shear horizontal mode, and the displacement becomes almost zero when the distance from the interface is larger than about two wavelengths. This means that if an overlaying layer 26 thicker than two wavelengths is present, a cavity package is not needed. Normally, for a PBAW device to function properly, its resonance frequency should be below the cut-off frequencies for the piezoelectric substrate and for the overlaying layer. This ensures that the boundary acoustic wave profile is evanescent both in the piezoelectric substrate and in the overlaying layer.

The electrode period P of the IDT 16 may at least partially define a wavelength λ at a resonance frequency fₛ of the PBAW device 10. For a single electrode IDT 16 such as the one shown in FIGS. 1A and 1B, at the resonance frequency fₛ, the wavelength λ is about twice the electrode period P (λ=2P). In other words, if sₓ is the wave slowness in the propagation direction along X-axis and fₛ is the resonance frequency, there is

$$\frac{1}{{s}_{x} {f}_{s}} = 2 p or {s}_{x} = \frac{1}{2 p {f}_{s}}$$

For the boundary acoustic wave to be evanescent in the vertical direction, the slowness sₓ must be large enough for the slownesses of all the modes in the vertical direction to be imaginary. Assuming regular convex slowness curves, this means in general that:

$${s}_{x} > {s}_{substrate} and {s}_{x} > {s}_{overlay}$$

where s_{substrate} and s_{overlay} are the slowness of the slowest wave in the overlaying layer and in the substrate. This is a typical guiding situation similar to what is seen on guided modes resonator for which the resonance frequency has to be lower than the cutoff frequency of the substrate. If the equation is expressed in term of frequency, there is

$${f}_{s} < \frac{{v}_{OVERLAY}}{2 p} and {f}_{s} < \frac{{v}_{SUBSTRATE}}{2 p}$$

which shows that the resonance frequency fₛ needs to be lower than the two cutoff frequencies. These conditions can be met by using a fast overlaying layer. If the overlaying layer is not fast enough (e.g., silicon oxide), another approach consists in reducing the resonance frequency by using thicker and/or heavier metal in the thickness hm of the electrodes of the IDT 16. For example, gold electrodes may be used other than copper. If the resonance is above the cutoff frequencies, some energy is dissipated in the substrate and/or the overlaying layer. This means that the top of the overlaying layer would have some acoustic displacement and it is not isolated. Some energy may be lost in the substrate and/or the overlaying layer. This may give a rise to losses and/or undesired modes.

The table below gives a list of materials and their acoustic velocities ordered according to their shear velocities.

| Material | Shear (m/s) | Longitudinal (m/s) |
|---|---|---|
| Aluminum | 3110 | 6422 |
| Silicon oxide | 3696 | 6035 |
| Lithium niobate | 3474/4043 | 6544 |
| (X propagation) | | |
| Silicon nitride | 5467 | 8759 |
| Aluminum nitride | 5809 | 10287 |

Taking lithium niobate as an example, for a propagation along X-axis the two shear modes have a velocity of 3474 m/s and 4043 m/s, respectively. If the crystal orientation is about Y-axis, then the shear horizontal mode is at 4043 m/s. The velocity of the shear mode in silicon oxide is between these two numbers, while it is larger for silicon nitride, aluminum nitride, and silicon. According to the discussion above, when a silicon oxide overlaying layer is used, the metal thickness hm of the electrodes needs to be large enough to have a resonance frequency significantly lower than 3696/(2p) to avoid bulk radiation. An alternative solution is to use heavy metals for the IDT, which increases material cost and manufacturing complexity. There are some advantages to choosing a fast material for the overlaying layer, such as an aluminum nitride overlaying layer. For the thinner electrodes, the lithium niobate bulk cutoff frequency may be between the resonance and antiresonance frequencies. This is due to the presence of the fast overlaying layer which pushes the resonance frequency up. If a slower overlaying layer, like silicon oxide or aluminum, is used, then the overlay cutoff frequency is lower and thick and/or dense electrodes are also necessary to avoid bulk radiation. This results in a smaller period for a given resonance frequency. For low frequency filters, this is an advantage because the result is a smaller die. When the goal is to design higher frequency filters, the electrode width becomes too narrow, and it has become quite challenging to manufacture an IDT with a large metal thickness. Using metallic materials in the overlaying layers presents the advantages of a better thermal conductivity and the overlaying layers may be used in the layout of the filter, such as for providing electrical connections. The best metals for the overlaying layers are the ones with the fastest acoustic velocities. Since the shear mode is the slowest elastic mode, metals with the fastest shear velocities are desirable. In general, the shear velocity should be larger than 2500 m/s or 2700 m/s. In addition to aluminum (shear velocity 3110 m/s), other suitable metals may include titanium (3120 m/s), molybdenum (3350 m/s), nickel (2970 m/s), tungsten (2970 m/s), chromium (about 4000 m/s), ruthenium (3729 m/s), or iridium (3050 m/s). Even if these metals have the fastest shear velocities, they are slower than the normal boundary wave velocity. This means that when these metals are used, the resonance frequency must normally be reduced by using heavy and/or thick electrodes.

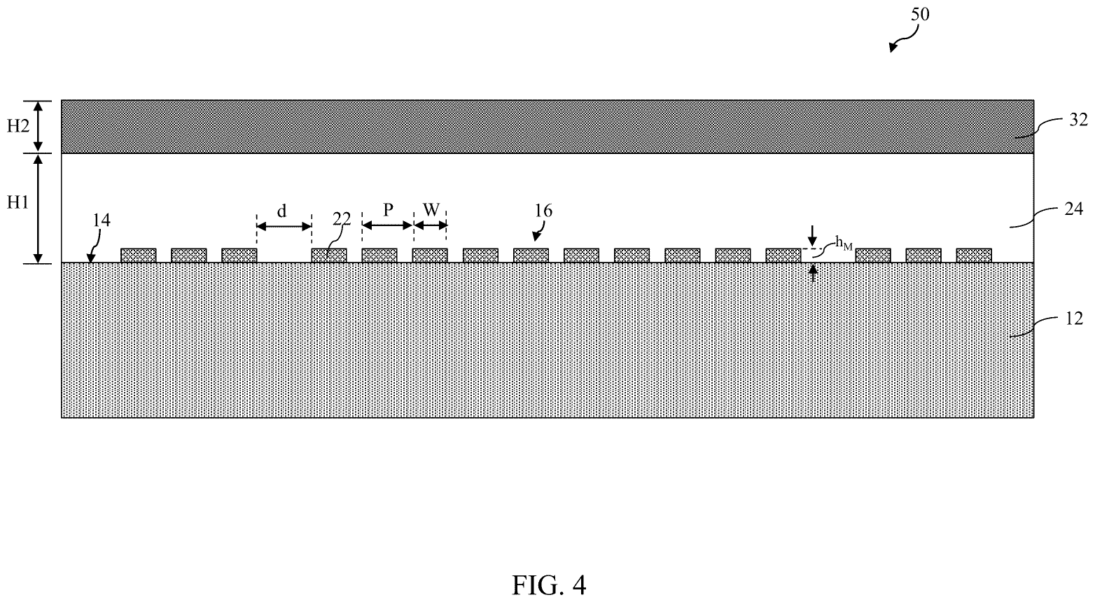

Reference is now made to FIG. 4, which illustrates an example of a PBAW device 50 that uses a metallic layer (or film) as an overlaying layer. Compared to FIG. 1B, the dielectric overlaying layer 26 is replaced by a metallic overlaying layer 32. In some embodiments, the embedding layer 24 is a silicon oxide (SiO₂) layer. In other embodiments, the embedding layer 24 may be some other dielectric material, such as silicon nitride (Si₃N₄), aluminum nitride (AlN), aluminum oxide (AlO), or hafnium oxide (HfO₂). In some embodiments, the metallic overlaying layer 32 is an aluminum layer or an aluminum alloy layer. In an instance of the embedding layer 24 being a silicon oxide (SiO₂) layer and the metallic overlaying layer 32 being an aluminum layer, even though aluminum is slower than silicon oxide, it is still possible to have the resonance frequency below the cutoff frequency.

The IDT 16 may use heavy metal as electrodes to have a sufficiently large electrode mass to push the resonant frequency below the aluminum cutoff frequency. In one instance, the IDT 16 may have a heavy metal (e.g., platinum, tungsten, or molybdenum) as a lower portion of the electrodes and a conductive material (e.g., copper or aluminum) stacked on the heavy metal as an upper portion of the electrodes.

The thickness of the embedding layer 24 (H1) and the thickness of the metallic overlaying layer 32 (H2) are also selected such that acoustical energy is negligeable at the top of the metallic layer. To achieve this, a sum of the thicknesses of the embedding layer 24 and the metallic overlaying layer 32 may be larger than 1.5 times of the electrode pitch P (i.e., H1+H2>1.5*P). The thickness of the metallic overlaying layer 32 itself, may be larger than the electrode pitch P (i.e., H2>P). In furtherance of some embodiments, the thickness of the metallic overlaying layer 32 may be larger than twice the electrode pitch P (i.e., H2>2*P). In some embodiments, the thickness of the embedding layer 24 is sufficiently large such that substantially no acoustical energy is presented in the metallic overlaying layer 32.

Instead of a dielectric overlaying layer, it is advantageous to use a metallic overlaying layer. The metallic overlaying layer generally improves thermal dissipation. Besides, since no acoustic energy is present on top of the metallic overlaying layer, it is possible to put it in contact with some other metal to help with the dissipation. Further, the metallic overlaying layer generally reduces layout losses and can improve electromagnetic isolation to the environment by metallic shielding. Using a metallic overlaying layer reduces the connection losses and reduces the space needed for the connection. If the overlaying layer is grounded, then the connection to a ground of shunt resonators would be easier. That is, the metallic overlay may be used as connections for a layout of a filter. Furthermore, since the top surface of the metallic overlaying layer is acoustically isolated, additional functional layers can be included on top for layouting or other features. For example, extra dielectric and metallic layers can be added on top of the metallic overlaying layer for signal routing, matching inductors or capacitors.

The metallic overlay may consist of a single layer; however, for process reasons or to combine the properties of different metallic materials, using several sublayers of different metallic compositions in the metallic overlay can be advantageous. It is beneficial to choose metals with the fastest acoustic velocities. In addition to aluminum, the metals might be molybdenum, titanium, tungsten, nickel, chromium, ruthenium, iridium or alloys. In one instance, the metallic overlay includes two sublayers, such as an aluminum sublayer and a molybdenum sublayer stacked above. In another instance, the metallic overlay includes three sublayers, such as an aluminum sublayer, a molybdenum sublayer, and a ruthenium sublayer stacked in sequence. Since chromium is easy to deposit and has a very fast velocity, combining aluminum (for conductivity) and chromium is a good option.

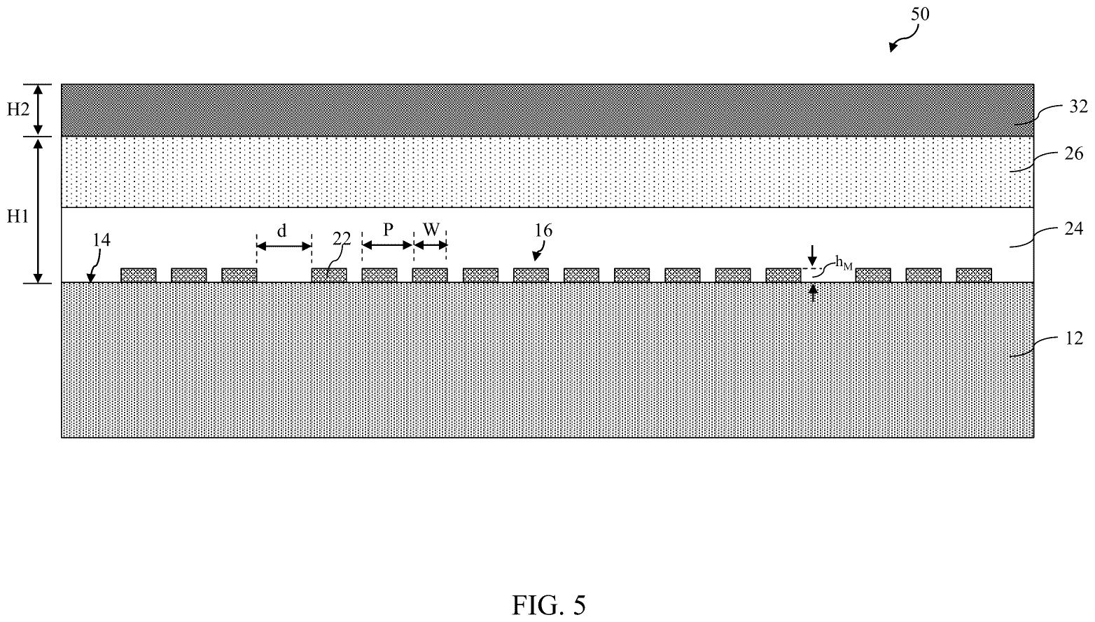

As discussed above, metallic overlaying layer 32 (e.g., aluminum) presents the advantage of contributing to the acoustic isolation of the resonators. If there is a sufficient thick overlay to suppress the acoustic energy at the surface of the metallic overlaying layer 32, it is possible to use other metallic materials (e.g., aluminum alloy, copper, titanium, tungsten, etc.) on top of the resonator, since from the acoustical aspect the choice of metallic materials would not be critical under this circumstance. The embedding layer 24 may also use dielectric material(s) other than silicon oxide (SiO₂). One good option may be to use aluminum nitride (AlN) below the metallic overlaying layer 32, as aluminum nitride (AlN) has the advantage of good thermal conductivity. In some embodiments, between the piezoelectric substrate 12 and the metallic overlaying layer 32, there may be a multi-layer dielectric structure. FIG. 5 illustrates such an embodiment. In FIG. 5, a dielectric overlaying layer 26 is stacked on the embedding layer 24. The embedding layer 24 may be a silicon oxide (SiO₂) layer, a hafnium oxide (HfO₂) layer, or a multilayer structure having two or more suitable dielectric materials (e.g., a first sublayer of silicon oxide, and a second sublayer of hafnium oxide). The dielectric overlaying layer 26 may be an aluminum nitride (AlN) layer, a hafnium oxide (HfO₂) layer, or a dielectric material layer of other suitable dielectric material(s). The overlaying layer 26 may be specifically chosen to have an acoustic velocity greater than that of the embedding layer 24. The sum of the thicknesses of the embedding layer 24 and the overlaying layer 26 (still represented by H1) and the thickness of the metallic overlaying layer 32 (H2) are selected such that acoustical energy is negligeable at the top of the metallic layer, as discussed above with reference to FIG. 4.

The piezoelectric substrate 12 may be made of lithium niobate (LN) or lithium tantalate (LT). In some embodiments, the piezoelectric substrate 12 has an orientation between Y−20° and Y+50°. In furtherance of some embodiments, the piezoelectric substrate 12 has an orientation between Y and Y+10°. In some other embodiments, the piezoelectric substrate 12 has an orientation between Y+110° and Y+130°. In furtherance of some embodiments, the piezoelectric substrate 12 has an orientation between Y+119° and Y+121°. These ranges are not trivial or arbitrary. The orientation within these ranges promotes stronger coupling and stronger suppression of the spurious modes (or even spurious free).

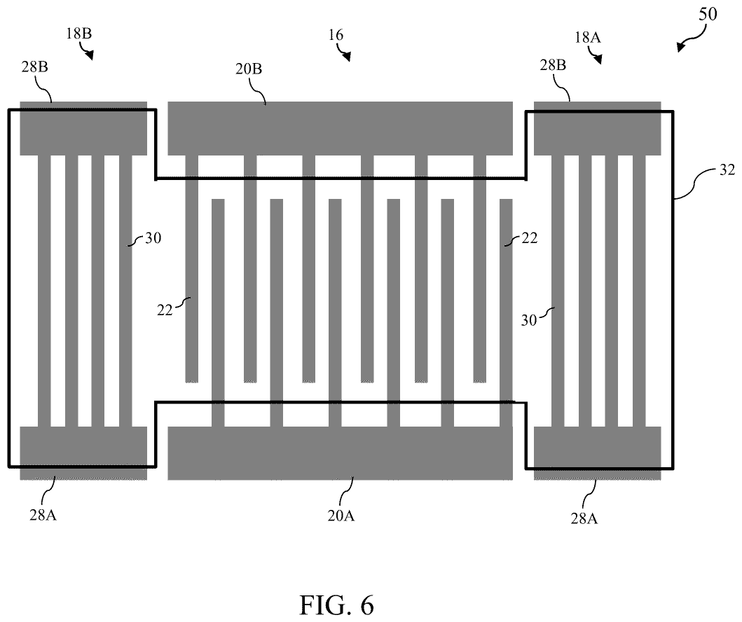

Reference is now made to FIG. 6, which illustrates a top view of the PBAW device 50, particularly the IDT 16, the reflector structures 18A and 18B, and the metallic overlaying layer 32. In the depicted embodiment, the metallic overlaying layer 32 has a dumbbell shape. The metallic overlaying layer 32 only partially overlaps with the IDT 16 with no overlapping portions with the busbars of the comb electrodes 20A and 20B. Such a configuration avoids adding a large shunt capacitance to the IDT 16. To avoid having overlapping portions with the busbars of the comb electrodes 20A and 20B, the metallic overlaying layer 32 also only partially overlaps with each of the electrode fingers 22 with no overlapping portions with the connecting ends of the electrode fingers 22. As a comparison, the metallic overlaying layer 32 fully covers the fingers 30 of the reflector structures 18A and 18B, and at least partially (or fully) overlaps with the busbar 28A and 28B of the reflector structures 18A and 18B. The metallic overlaying layer 32 may be electrically coupled to the ground of the PBAW device 50 or electrically floating. In some embodiments, the metallic overlaying layer 32 may be connected to grounded busbars. For example, a plurality of through vias (not shown) vertically extending from the busbars 28A and 28B and ended at the metallic overlaying layer 32 may provide electrical grounding to the metallic overlaying layer 32.

In some alternative embodiments, the metallic overlaying layer 32 may partially or fully overlap with the busbars of the comb electrodes 20A and 20B and thus fully overlap with each of the electrode fingers 22 of the IDT 16. Such overlapping with the busbars of the comb electrodes 20A and 20B provides a degree of freedom in scenarios where additional capacitance is intentionally desired to alter the coupling of some resonators. Furthermore, if there is an overlap between the metallic overlaying layer 32 and the busbars of the comb electrodes 20A and 20B, through vias may be provided to vertically extend from the busbars of the comb electrodes 20A and 20B to the metallic overlaying layer 32, offering electrical connection or additional capacitance.

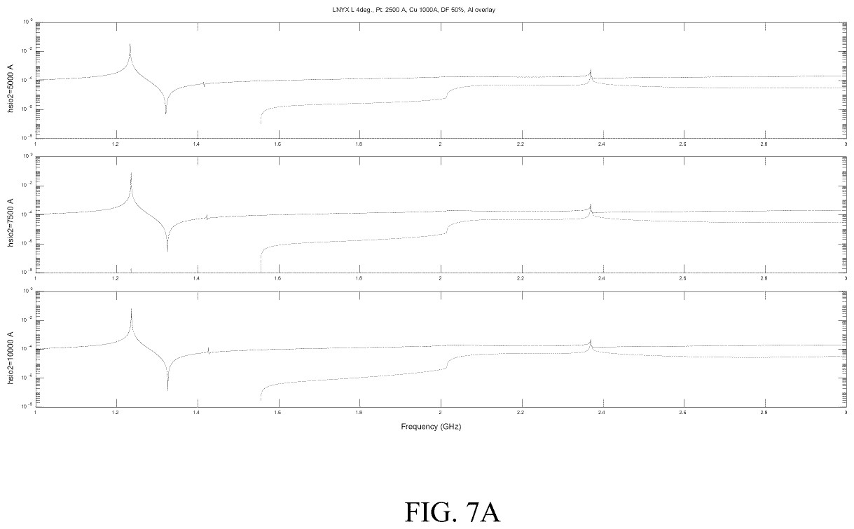

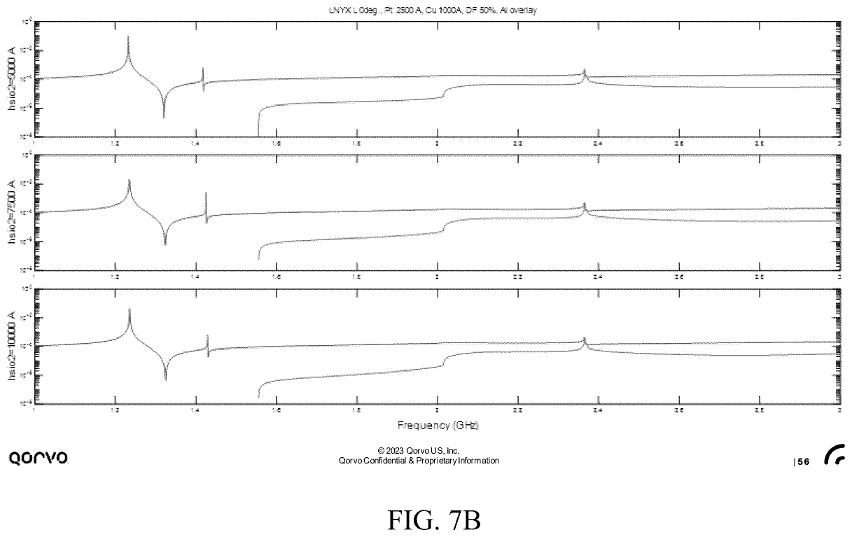

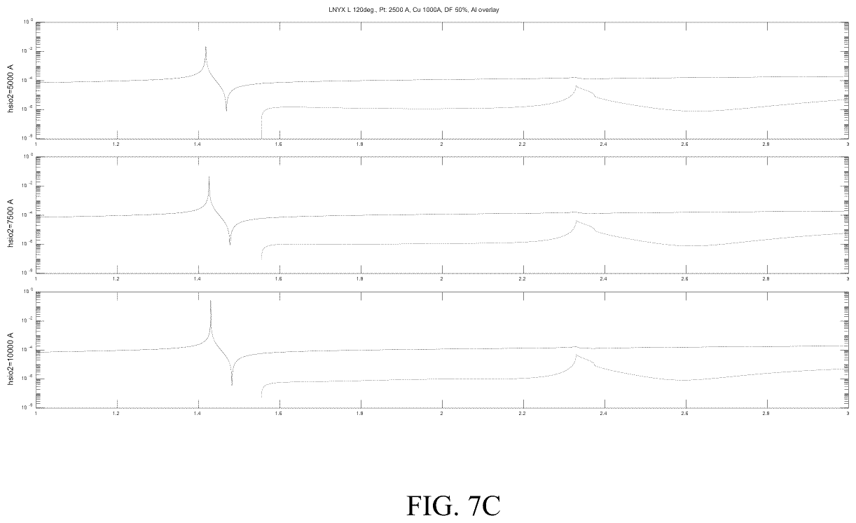

FIGS. 7A, 7B, and 7C illustrate periodic FEM simulation results for an aluminum overlaying layer 32 with an infinite thickness disposed on an LN piezoelectric substrate 12 with different crystalline orientations, namely YX, Y+4° in FIG. 7A, YX, Y+0° in FIG. 7B, and YX, Y+120° in FIG. 7C. The aluminum overlaying layer 32 is separated from the LN piezoelectric substrate 12 by an embedding layer of silicon oxide with various thicknesses (5000 Å, 7500 Å, 10000 Å). The electrodes have a period of 1 um and a duty factor of 50%. The electrodes have a multi-layer structure with a platinum lower portion of 2500 Å and a copper upper portion of 1000 Å. For the orientation within YX, Y+0° ˜ Y+4°, the shear horizontal mode is excited, and the simulated coupling is about 15.7%. A spurious mode exists and can be reduced by further optimizing the crystalline orientation and electrode thickness. If the orientation is around YX, Y+120°, a Stoneley-like mode is excited. The coupling factor is about 8% and the response is substantially without spurious. The aluminum cutoff frequency is relatively close to the resonance.

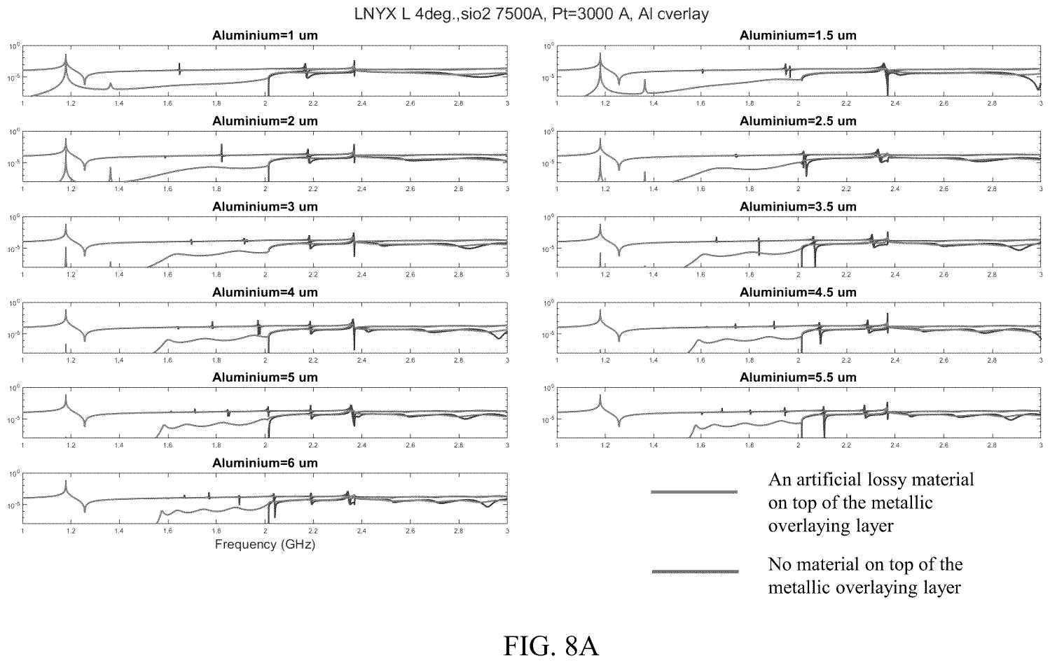

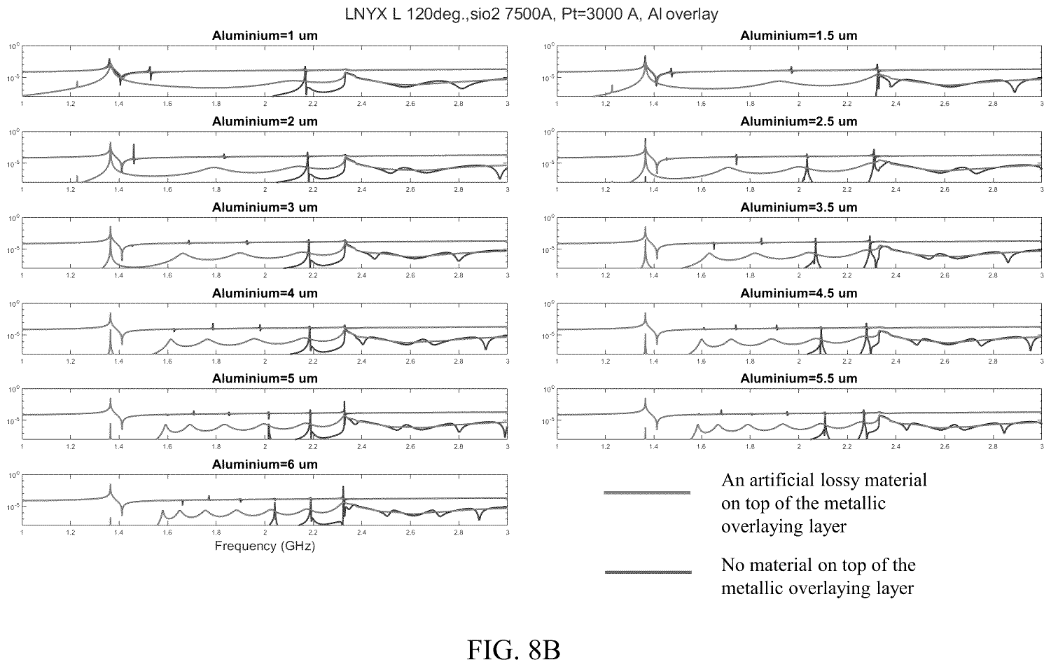

FIGS. 8A and 8B illustrate periodic FEM simulation results for an aluminum overlaying layer 32 with various thicknesses (1 um, 1.5 um, 2 um, 2.5 um, 3 um, 3.5 um, 4 um, 4.5 um, 5 um, 5.5 um, 6 um) for respectively the YX, Y+4° and YX, Y+120° orientations. The aluminum overlaying layer 32 is separated from the LN piezoelectric substrate 12 by an embedding layer of silicon oxide with a thickness of 7500 Å. The top of the overlay is assumed to be free, or an artificial infinite thickness lossy material is added to estimate the variation of quality factor with the overlay thickness. The electrodes have a period of 1 um and a duty factor of 50%. The electrodes have a multi-layer structure with a platinum lower portion of 3000 Å and a copper upper portion of 1000 Å.

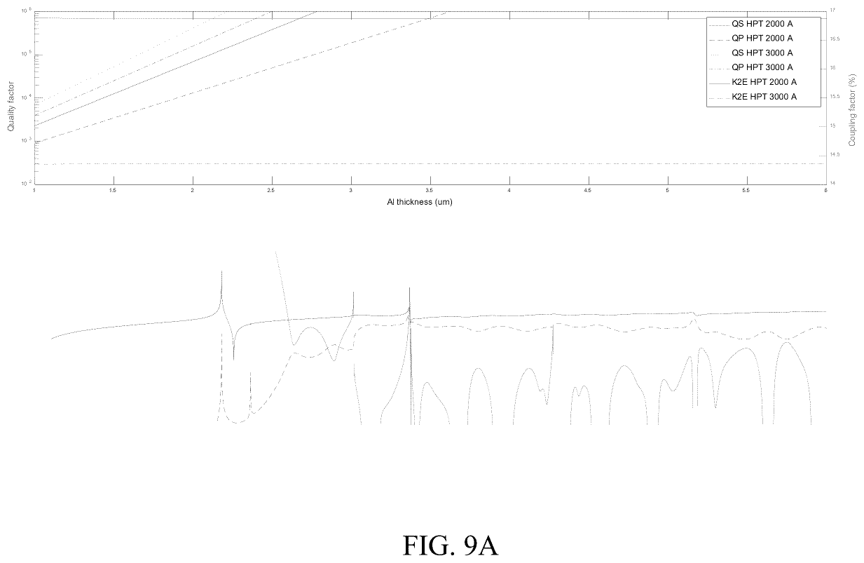

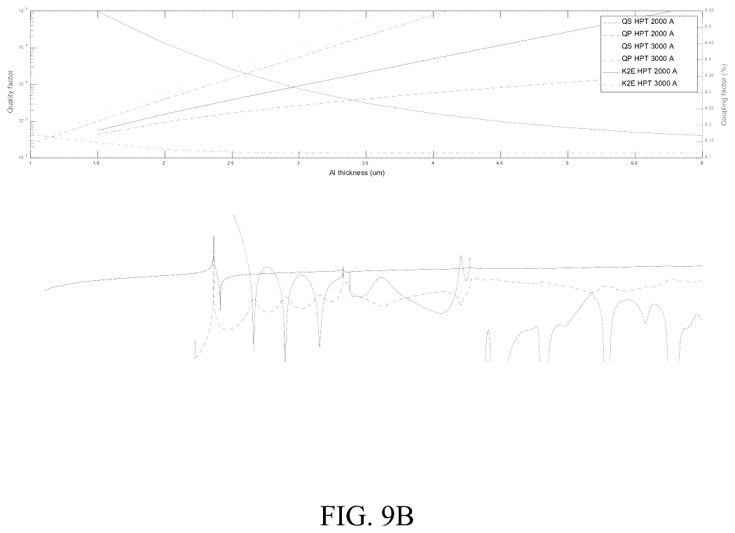

FIGS. 9A and 9B illustrate the simulation variations of the quality factor and coupling factor with the aluminum thickness (sweeping from 1 um to 6 um) for respectively the YX, Y+4° and YX, Y+120° orientations. The electrodes have a period of 1 um and a duty factor of 50%. The top sub-figure shows variation of Q at resonance (Qs), at antiresonance (Qp) and coupling factor vs aluminum thickness when an infinite lossy material is above the aluminum. The electrodes consist of a 2000 Å or 3000 Å platinum layer and a 1000 Å copper layer. The bottom sub-figure shows an example of admittance and conductance for 3000 Å platinum and 2 um aluminum. It is found that the quality factor stays larger than 10,000 when the aluminum thickness is larger than 2 um (1λ) for the Y+4° orientation. For the Y+120° orientation, the quality factor stays larger than 10,000 when the Pt thickness is 3000 Å and the aluminum thickness is larger than 2 um (1λ). For 2000 Å platinum, about two 2 are necessary for the platinum. This is due to the proximity of the cutoff frequency.

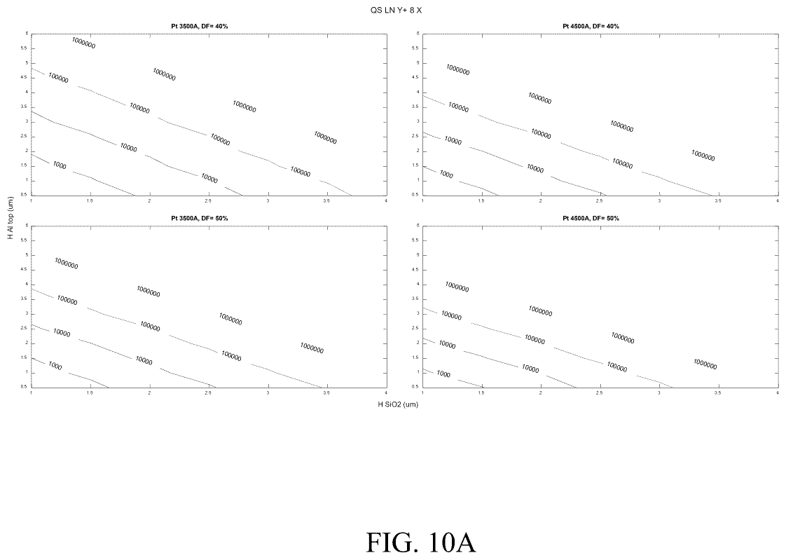

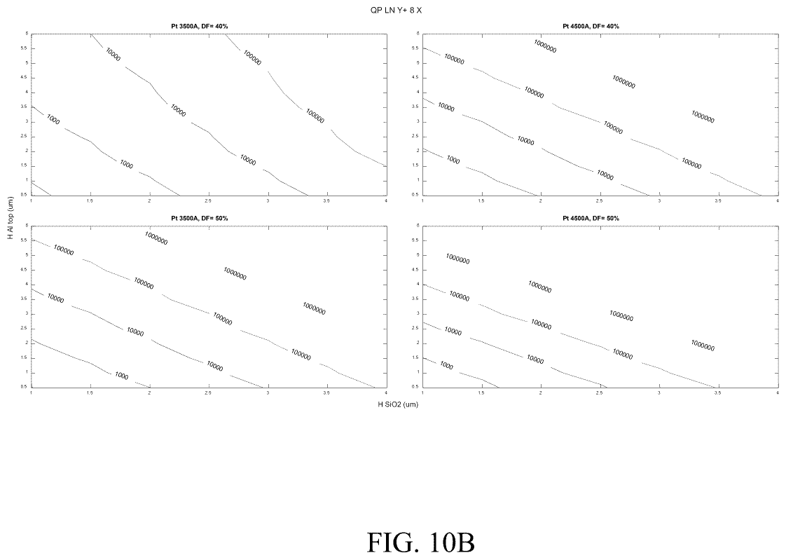

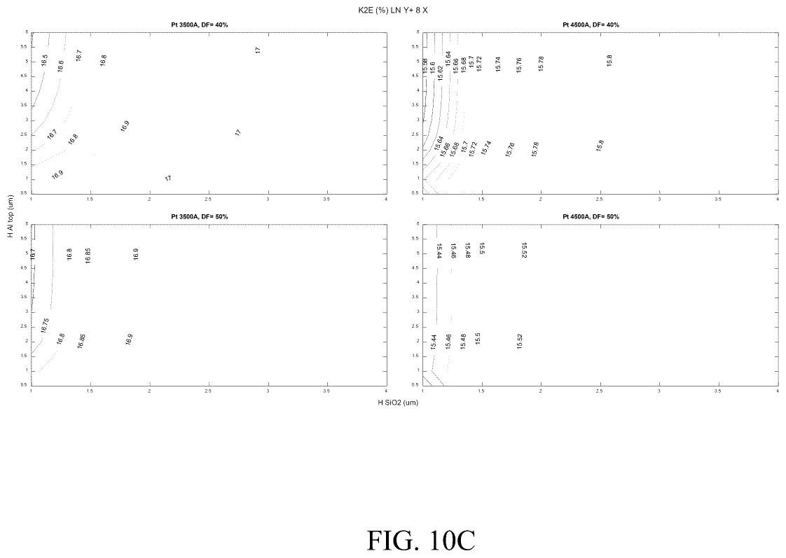

It is possible to combine a metallic overlaying layer (e.g., an aluminum film) with another overlay, like for example silicon oxide. If the layer of silicon oxide is thick, then the thickness of the aluminum overlay to obtain a good quality factor is thinner than without oxide. FIGS. 10A, 10B, and 10C illustrate periodic FEM simulation results for an overlay of a combination of silicon oxide and aluminum on a YX, Y+8° piezoelectric substrate. The electrodes have a period of 1.6 um with a respective duty factor of 40% or 50%. The electrodes consist of platinum of 3500 Å or 4500 Å. FIGS. 10A and 10B respectively show the variation of the quality factor at resonance and antiresonance versus the thickness of oxide and aluminum. It shows that oxide and aluminum play a similar role. FIG. 10C shows the evolution of the coupling factor for the same case. The thickness has an impact on the coupling factor, but this impact is minor.

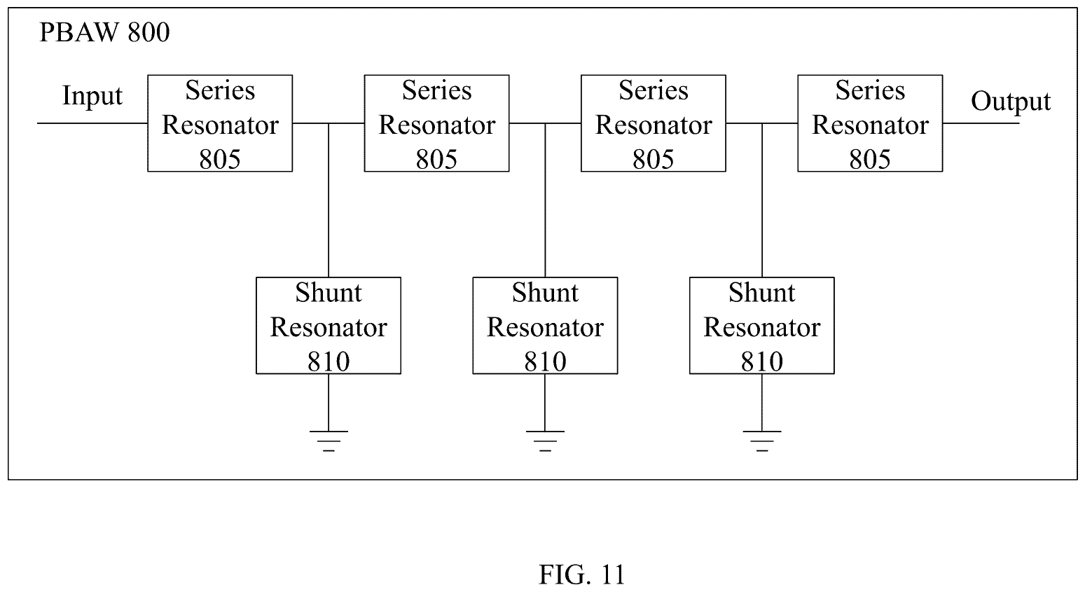

FIG. 11 depicts a high level example of a PBAW device 800, such as the PBAW device 50. In embodiments, the PBAW device 800 may have several resonators such as series resonators 805, which may be similar to resonators 16 of a first type, or shunt resonators 810, which may be similar to resonators 16 of a second type. In general, each of the series resonators 805 may have similar electrode periods and/or frequency features. Similarly, each of the shunt resonators 810 may have similar electrode periods and/or frequency features. Although a certain number and configuration of series resonators 805 and shunt resonators 810 are shown here for PBAW device 800, other embodiments may have different numbers or configurations of series and shunt resonators 805 and 810. In embodiments, each of the resonators may have resonance frequencies, fR, and anti-resonance frequencies, fA. In embodiments, the shunt resonators 810 may all have similar resonance and anti-resonance frequencies to one another, and the series resonators 805 may all have similar resonance and anti-resonance frequencies to one another. In embodiments, the difference between fR and fA of the series resonators may be approximately equal to the difference between fR and fA of the shunt resonators. In some embodiments, fA of the shunt resonators may be approximately equal to fR of the series resonators. The performances may be improved by connecting several reactive elements for example inductances in series or in parallel with one or several resonators. More complex filter topologies may be used as it is well known. Also, all the topologies used for designing SAW or BAW filters or duplexers, not shown in the figures may be used. In particular, coupled resonator filters which involve the acoustic coupling of several transducers between reflectors may be used and combined or not with resonators in series and/or in parallel.

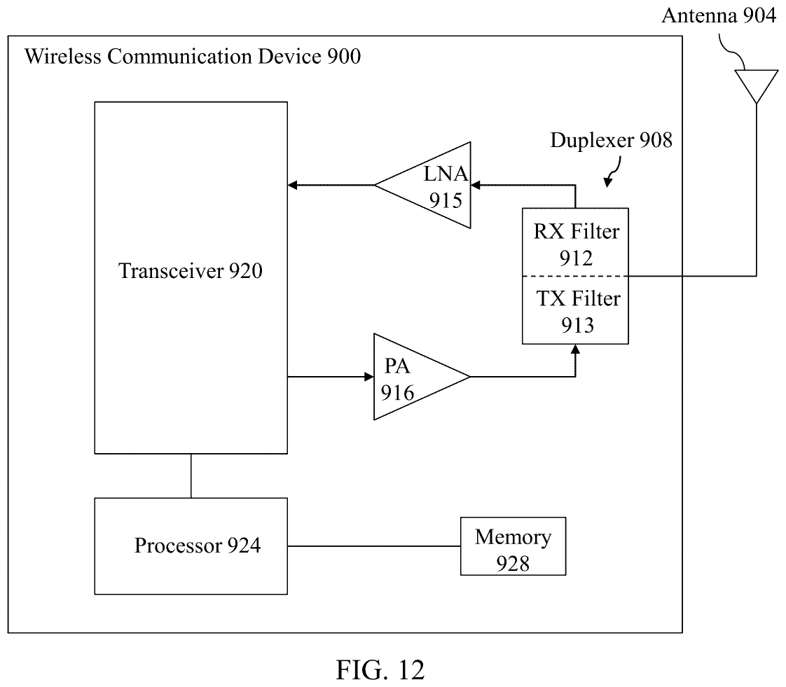

FIG. 12 illustrates a wireless communication device 900, which implements the PBAW device 50 or the PBAW device 800. The wireless communication device 900 may have an antenna structure 904, a duplexer 908 (containing an RX filter 912 and a TX filter 913), a power amplifier (PA) 916, a low noise amplifier (LNA) 915, a transceiver 920, a processor 924, and a memory 928 coupled with each other at least as shown.

The antenna structure 904 may include one or more antennas to transmit and receive radio frequency (RF) signals over the air. The antenna structure 904 may be coupled with the duplexer 908 that operates to selectively couple the antenna structure with the LNA 915 or the PA 916. When transmitting outgoing RF signals, the TX filter 913 may couple the antenna structure 904 with the PA 916. When receiving incoming RF signals, the RX filter 912 may couple the antenna structure 904 with the LNA 915. The RX and TX filters 912 and 913 may include one or more PBAW devices, such as PBAW devices 50 or 800. In some embodiments, the RX and TX filters 912 and 913 may include a first plurality of series resonators and a second plurality resonators. The RX filter 912 may filter the RF signals received from the antenna structure 904 and pass portions of the RF signals within a predetermined bandpass to the transceiver 920.

When transmitting outgoing RF signals, the duplexer 908 may couple the antenna structure 904 with the PA 916. The PA 916 may receive RF signals from the transceiver 920, amplify the RF signals, and provide the RF signals via the TX filter 913 to the antenna structure 904 for over-the-air transmission.

The processor 924 may execute a basic operating system program, stored in the memory 928, in order to control the overall operation of the wireless communication device 900. For example, the processor 924 may control the reception of signals and the transmission of signals by transceiver 920. The processor 924 may be capable of executing other processes and programs resident in the memory 928 and may move data into or out of memory 928, as desired by an executing process.

The transceiver 920 may receive outgoing data (e.g., voice data, web data, e-mail, signaling data, etc.) from the processor 924, may generate RF signals to represent the outgoing data, and provide the RF signals to the PA 916. Conversely, the transceiver 920 may receive RF signals from the filter 912 that represent incoming data. The transceiver 920 may process the RF signals and send incoming signals to the processor 924 for further processing.

In various embodiments, the wireless communication device 900 may be, but is not limited to, a mobile telephone, a paging device, a personal digital assistant, a text-messaging device, a portable computer, a desktop computer, a base station, a subscriber station, an access point, a radar, a satellite communication device, or any other device capable of wirelessly transmitting/receiving RF signals.

In accordance with one or more embodiments, a piezoelectric boundary acoustic wave (PBAW) device is provided. The PBAW includes a piezoelectric substrate; an interdigital transducer on the piezoelectric substrate, the interdigital transducer having electrodes arranged with an electrode period; a dielectric embedding layer with the electrodes embedded therein; and a metallic overlaying layer on the dielectric embedding layer.

In one or more embodiments, the dielectric embedding layer, the metallic overlaying layer, and the interdigital transducer are configured such that acoustical energy is negligeable at a top surface of the metallic overlaying layer.

In one or more embodiments, the metallic overlaying layer is made of aluminum or aluminum alloy. In one or more embodiments, the metallic overlaying layer is made of one of aluminum, molybdenum, titanium, nickel, tungsten, chromium, ruthenium, iridium, or alloys thereof. In one or more embodiments, the metallic overlaying layer is made of a metal with a shear velocity larger than 2500 m/s or 2700 m/s.

In one or more embodiments, the metallic overlaying layer includes a plurality of sublayers of different material compositions.

In one or more embodiments, the dielectric embedding layer includes a plurality of sublayers of different material compositions. In one or more embodiments, the dielectric embedding layer is made of silicon oxide or hafnium oxide.

In one or more embodiments, the piezoelectric substrate is made of lithium tantalate. In one or more embodiments, the piezoelectric substrate is made of lithium niobate. In one or more embodiments, the piezoelectric substrate has a crystalline orientation between Y−20° and Y+50°. In one or more embodiments, the piezoelectric substrate has a crystalline orientation between Y+0° and Y+10°. In one or more embodiments, the piezoelectric substrate has a crystalline orientation between Y+110° and Y+130°. In one or more embodiments, the piezoelectric substrate has a crystalline orientation between Y+119° and Y+121°.

In one or more embodiments, the electrodes are configured to have a mass sufficiently large to push a resonance frequency below a cutoff frequency of the metallic overlaying layer. In one or more embodiments, the dielectric embedding layer includes aluminum nitride.

In one or more embodiments, the metallic overlaying layer is electrically connected to a ground of the PBAW device. In one or more embodiments, the metallic overlaying layer is used as connections for a layout of a filter. In one or more embodiments, the electrodes include a heavy material selected from platinum, tungsten, and silver and a conductive material selected from copper and aluminum.

In accordance with one or more embodiments, a piezoelectric boundary acoustic wave (PBAW) device is provided. The PBAW includes a piezoelectric substrate; an interdigital transducer on the piezoelectric substrate, the interdigital transducer having electrodes arranged with an electrode period; dielectric embedding layers with the electrodes embedded therein; and metallic overlaying layers on the dielectric embedding layer, wherein a thickness of the metallic overlaying layer is larger than the electrode period.

In one or more embodiments, a thickness of the metallic overlaying layers is larger than twice the electrode period. In one or more embodiments, a sum of a thickness of the dielectric embedding layers and a thickness of the metallic overlaying layers is larger than 1.5 times the electrode period. In one or more embodiments, the dielectric embedding layers are configured to have a thickness sufficiently large to exclude acoustical energy in the metallic overlaying layers.

In one or more embodiments, the dielectric embedding layer, the metallic overlaying layer, and the interdigital transducer are configured such that acoustical energy is negligeable at a top surface of the metallic overlaying layer.

In one or more embodiments, the metallic overlaying layer is made of aluminum or aluminum alloy. In one or more embodiments, the metallic overlaying layer is made of one of aluminum, molybdenum, titanium, nickel, tungsten, chromium, ruthenium, iridium, or alloys thereof. In one or more embodiments, the metallic overlaying layer is made of a metal with a shear velocity larger than 2500 m/s or 2700 m/s.

In one or more embodiments, the metallic overlaying layer includes a plurality of sublayers of different material compositions.

In one or more embodiments, the dielectric embedding layer includes a plurality of sublayers of different material compositions. In one or more embodiments, the dielectric embedding layer is made of silicon oxide or hafnium oxide.

In one or more embodiments, the piezoelectric substrate is made of lithium tantalate. In one or more embodiments, the piezoelectric substrate is made of lithium niobate. In one or more embodiments, the piezoelectric substrate has a crystalline orientation between Y−20° and Y+50°. In one or more embodiments, the piezoelectric substrate has a crystalline orientation between Y+0° and Y+10°. In one or more embodiments, the piezoelectric substrate has a crystalline orientation between Y+110° and Y+130°. In one or more embodiments, the piezoelectric substrate has a crystalline orientation between Y+119° and Y+121°.

In one or more embodiments, the electrodes are configured to have a mass sufficiently large to push a resonance frequency below a cutoff frequency of the metallic overlaying layer. In one or more embodiments, the dielectric embedding layer includes aluminum nitride.

In one or more embodiments, the metallic overlaying layer is electrically connected to a ground of the PBAW device. In one or more embodiments, the metallic overlaying layer is used as connections for a layout of a filter. In one or more embodiments, the electrodes include a heavy material selected from platinum, tungsten, and silver and a conductive material selected from copper and aluminum.

In accordance with one or more embodiments, a wireless device comprising a boundary acoustic wave device is provided. The boundary acoustic wave device includes a piezoelectric substrate; an interdigital transducer on the piezoelectric substrate, the interdigital transducer having electrodes arranged with an electrode period; dielectric embedding layers with the electrodes embedded therein; and metallic overlaying layers on the dielectric embedding layer, wherein the piezoelectric substrate has a crystalline orientation between Y+110° and Y+130°.

In one or more embodiments, a thickness of the metallic overlaying layer is larger than the electrode period. In one or more embodiments, a thickness of the metallic overlaying layers is larger than twice the electrode period. In one or more embodiments, a sum of a thickness of the dielectric embedding layers and a thickness of the metallic overlaying layers is larger than 1.5 times the electrode period. In one or more embodiments, the dielectric embedding layers are configured to have a thickness sufficiently large to exclude acoustical energy in the metallic overlaying layers.

In one or more embodiments, the dielectric embedding layer, the metallic overlaying layer, and the interdigital transducer are configured such that acoustical energy is negligeable at a top surface of the metallic overlaying layer.

In one or more embodiments, the metallic overlaying layer is made of aluminum or aluminum alloy. In one or more embodiments, the metallic overlaying layer is made of one of aluminum, molybdenum, titanium, nickel, tungsten, chromium, ruthenium, iridium, or alloys thereof. In one or more embodiments, the metallic overlaying layer is made of a metal with a shear velocity larger than 2500 m/s or 2700 m/s.

In one or more embodiments, the metallic overlaying layer includes a plurality of sublayers of different material compositions.

In one or more embodiments, the dielectric embedding layer includes a plurality of sublayers of different material compositions. In one or more embodiments, the dielectric embedding layer is made of silicon oxide or hafnium oxide.

In one or more embodiments, the piezoelectric substrate is made of lithium tantalate. In one or more embodiments, the piezoelectric substrate is made of lithium niobate. In one or more embodiments, the piezoelectric substrate has a crystalline orientation between Y−20° and Y+50°. In one or more embodiments, the piezoelectric substrate has a crystalline orientation between Y+0° and Y+10°. In one or more embodiments, the piezoelectric substrate has a crystalline orientation between Y+119° and Y+121°.

In one or more embodiments, the electrodes are configured to have a mass sufficiently large to push a resonance frequency below a cutoff frequency of the metallic overlaying layer. In one or more embodiments, the dielectric embedding layer includes aluminum nitride.

In one or more embodiments, the metallic overlaying layer is electrically connected to a ground of the PBAW device. In one or more embodiments, the metallic overlaying layer is used as connections for a layout of a filter. In one or more embodiments, the electrodes include a heavy material selected from platinum, tungsten, and silver and a conductive material selected from copper and aluminum.

Those skilled in the art will recognize that the wireless communication device 900 is given by way of example and that, for simplicity and clarity, only so much of the construction and operation of the wireless communication device 900 as is necessary for an understanding of the embodiments is shown and described. Various embodiments contemplate any suitable component or combination of components performing any suitable tasks in association with wireless communication device 900, according to particular needs. Moreover, it is understood that the wireless communication device 900 should not be construed to limit the types of devices in which embodiments may be implemented.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A piezoelectric boundary acoustic wave (PBAW) device, comprising:
a piezoelectric substrate;
an interdigital transducer on the piezoelectric substrate, the interdigital transducer having electrodes arranged with an electrode period;
a dielectric embedding layer with the electrodes embedded therein; and
a metallic overlaying layer on the dielectric embedding layer.

2. The PBAW device of claim 1, wherein the dielectric embedding layer, the metallic overlaying layer, and the interdigital transducer are configured such that acoustical energy is negligeable at a top surface of the metallic overlaying layer.

3. The PBAW device of claim 1, wherein the metallic overlaying layer is made of one of aluminum, molybdenum, titanium, nickel, tungsten, chromium, ruthenium, iridium, or alloys thereof.

4. The PBAW device of claim 1, wherein the dielectric embedding layer includes a plurality of sublayers of different material compositions.

5. The PBAW device of claim 1, wherein the dielectric embedding layer is made of silicon oxide or hafnium oxide.

6. The PBAW device of claim 1, wherein the piezoelectric substrate has a crystalline orientation between Y−20° and Y+50°.

7. The PBAW device of claim 1, wherein the piezoelectric substrate has a crystalline orientation between Y+110° and Y+130°.

8. The PBAW device of claim 1, wherein the electrodes are configured to have a mass sufficiently large to push a resonance frequency below a cutoff frequency of the metallic overlaying layer.

9. The PBAW device of claim 1, wherein the electrodes include a heavy material selected from platinum, tungsten, and silver and a conductive material selected from copper and aluminum.

10. A piezoelectric boundary acoustic wave (PBAW) device, comprising:
a piezoelectric substrate;
an interdigital transducer on the piezoelectric substrate, the interdigital transducer having electrodes arranged with an electrode period;
dielectric embedding layers with the electrodes embedded therein; and
metallic overlaying layers on the dielectric embedding layer, wherein a thickness of the metallic overlaying layer is larger than the electrode period.

11. The PBAW device of claim 10, wherein a thickness of the metallic overlaying layers is larger than twice the electrode period.

12. The PBAW device of claim 10, wherein a sum of a thickness of the dielectric embedding layers and a thickness of the metallic overlaying layers is larger than 1.5 times the electrode period.

13. The PBAW device of claim 10, wherein the dielectric embedding layers are configured to have a thickness sufficiently large to exclude acoustical energy in the metallic overlaying layers.

14. The PBAW device of claim 10, wherein the piezoelectric substrate has a crystalline orientation between Y−20° and Y+50°.

15. A wireless device, comprising:
a boundary acoustic wave device, comprising:
a piezoelectric substrate;
an interdigital transducer on the piezoelectric substrate, the interdigital transducer having electrodes arranged with an electrode period;
dielectric embedding layers with the electrodes embedded therein; and
metallic overlaying layers on the dielectric embedding layer, wherein the piezoelectric substrate has a crystalline orientation between Y+110° and Y+130°.

16. The wireless device of claim 15, wherein a thickness of the metallic overlaying layers is larger than twice the electrode period.

17. The wireless device of claim 15, wherein a sum of a thickness of the dielectric embedding layers and a thickness of the metallic overlaying layers is larger than 1.5 times the electrode period.

18. The wireless device of claim 15, wherein the dielectric embedding layer, the metallic overlaying layer, and the interdigital transducer are configured such that acoustical energy is negligeable at a top surface of the metallic overlaying layer.

19. The wireless device of claim 15, wherein the dielectric embedding layer includes a plurality of sublayers of different material compositions.

20. The wireless device of claim 15, wherein the electrodes include a heavy material selected from platinum, tungsten, and silver and a conductive material selected from copper and aluminum.
